(19) United States
(12) Patent Application Publication
(10) Pub. No.: US 2026/0353562 A1
(43) Pub. Date: Nov. 5, 2026

(54) MULTILAYER WIRING BASE SUBSTRATE, MULTILAYER WIRING BOARD, AND METHOD FOR MANUFACTURING MULTILAYER WIRING BOARD

(71) Applicant: TOPPAN Holdings Inc., Tokyo (JP)

(72) Inventor: Tsukasa NAKAMURA, Tokyo (JP)

(73) Assignee: TOPPAN Holdings Inc., Tokyo (JP)

(21) Appl. No.: 19/719,696

(22) Filed: Jun. 25, 2026

Related U.S. Application Data
(63) Continuation of application No. PCT/JP2024/043754, filed on Dec. 11, 2024.

(30) Foreign Application Priority Data
Dec. 28, 2023 (JP) 2023-222776

(51) Int. Cl. H05K 1/14; H05K 1/02; H05K 3/36

(52) U.S. Cl. CPC H05K 1/144; H05K 1/0298; H05K 3/368; H05K 2201/041

(57) ABSTRACT

A technique that enables preventing delamination between the resin and the core substrate to ensure the reliability of multilayer wiring boards is provided. A multilayer wiring base substrate includes a plurality of multilayer wiring boards bonded together, each multilayer wiring board including a core substrate having a first surface, a second surface opposing the first surface, and a side surface portion connecting a peripheral portion of the first surface and a peripheral portion of the second surface; a first wiring layer formed on the first surface; and a second wiring layer formed on the second surface. Each of the multilayer wiring boards has at least the side surface portion of the core substrate covered with a metal member and an insulating resin in this order from a center side of the core substrate, and is bonded to at least one other multilayer wiring board via the insulating resin.

### CROSS-REFERENCE TO RELATED APPLICATIONS

This application claims benefit of priority to International Patent Application No. PCT/JP2024/043754, filed Dec. 11, 2024, and to Japanese Patent Application No. 2023-222776, filed Dec. 18, 2023, the entire contents of each are incorporated herein by reference.

### BACKGROUND

### Technical Field

The present disclosure relates to a multilayer wiring base substrate, a multilayer wiring board, and a method for manufacturing a multilayer wiring board.

### Background Art

The need for higher-density wiring boards for semiconductor devices is growing as electronic devices become more functional and smaller. Along with the miniaturization of circuit wiring, miniaturization of passive components such as resistors, capacitors, and inductors is also required. However, there is a limit to further miniaturization by relying solely on the miniaturization of these passive components and high-density mounting on the substrate surface.

Therefore, a technique for embedding passive elements into the mounting substrate has been proposed.

For example, JP 2000-151114 A discloses the following multilayer substrate and manufacturing method thereof, with the aim of providing a multilayer substrate incorporating passive elements and a manufacturing method thereof capable of achieving high performance and high precision of the passive elements.

“The ceramic multilayer substrate is divided into four blocks B1, B2, B3, and B4. The block B1 has two laminated insulating layers made of AlN. The block B2 has two laminated insulating layers made of high-purity alumina, with resistance elements R1 and R2 formed on the upper insulating layer. The block B3 is a single insulating layer made of glass ceramic, with capacitors C1 and C2 formed on it. The block B4 has four laminated insulating layers made of zirconia. These blocks B1, B2, B3, and B4 are mechanically and electrically bonded by an insulating bonding material 11 and a conductive bonding material 12 interposed between the blocks.”

In this technique, passive elements are formed by printing, vacuum deposition, or the like for incorporation into multilayer substrates. In addition to miniaturization, the reduced wiring length also provides the effect of reducing high-frequency noise.

Meanwhile, organic materials, typically glass epoxy resin, have generally been used as materials for wiring boards. In recent years, advances in hole-forming technology for glass materials have made it possible to, for example, form small-diameter through-holes of 100 μm or less at a pitch of 150 μm or less in a 300 μm thick glass substrate. As a result, glass has gained significant attention as a material for electronic circuit boards.

Circuit boards using glass materials as the core substrate, hereinafter referred to as “glass circuit boards”, offer high mounting reliability because glass has a small coefficient of linear thermal expansion (CTE) of 2 ppm to 8 ppm, which matches the CTE of silicon chips. Furthermore, the good flatness enables high-precision mounting and also has a positive effect on fine wiring formability and high-speed transmission characteristics.

### SUMMARY

When forming a multilayer wiring board by forming wiring layers on the upper and lower surfaces of a glass circuit board, during singulation of the multilayer wiring board from a base substrate, stress in the wiring layers may cause delamination between the glass serving as the core substrate and the resin forming the wiring layers, resulting in fracture of the glass circuit board. One factor contributing to fracture is considered to be the occurrence of microcracks, hereinafter also referred to as “μ-cracks”, in the glass circuit board. Therefore, it has been difficult to ensure the reliability of multilayer wiring boards using a glass material as the core substrate.

Therefore, an object of the present disclosure is to provide a technique that enables preventing delamination between the resin and the core substrate to ensure the reliability of multilayer wiring boards.

To solve the above problem, a representative multilayer wiring base substrate according to the present disclosure includes a plurality of multilayer wiring boards bonded together, each multilayer wiring board including a core substrate having a first surface, a second surface opposing the first surface, and a side surface portion connecting a peripheral portion of the first surface and a peripheral portion of the second surface; a first wiring layer that is a wiring layer formed on the first surface; and a second wiring layer that is a wiring layer formed on the second surface. Each of the multilayer wiring boards has at least the side surface portion of the core substrate covered with a metal member and an insulating resin in this order from a center side of the core substrate, and is bonded to at least one other multilayer wiring board via the insulating resin.

According to the present disclosure, it is possible to prevent delamination between the resin and the core substrate and ensure the reliability of multilayer wiring boards.

Problems, configurations, and effects other than those described above will become clear from the following description of embodiments.

### BRIEF DESCRIPTION OF THE DRAWINGS

FIGS. 1A, 1B and 1C show diagrams illustrating a multilayer wiring board according to the first embodiment.

FIG. 2 is a cross-sectional view illustrating the structure of a through-electrode in the multilayer wiring board according to the first embodiment.

FIG. 3 is a cross-sectional view illustrating the bonding step of the first support in the manufacturing method according to the first embodiment.

FIG. 4 is a cross-sectional view illustrating the step of forming laser-modified portions in the manufacturing method according to the first embodiment.

FIGS. 5A, 5B and 5C show diagrams illustrating the locations where the laser-modified portions are formed in the manufacturing method according to the first embodiment.

FIG. 6 is a cross-sectional view illustrating the step of forming the first wiring layer in the manufacturing method according to the first embodiment.

FIG. 7 is a cross-sectional view illustrating the bonding step of the second support in the manufacturing method according to the first embodiment.

FIG. 8 is a cross-sectional view illustrating the removal step of the first support in the manufacturing method according to the first embodiment.

FIG. 9 is a cross-sectional view illustrating the step of forming the through-holes by etching in the manufacturing method according to the first embodiment.

FIG. 10 is a cross-sectional view illustrating the step of forming the second wiring layer in the manufacturing method according to the first embodiment.

FIG. 11 is an enlarged view of the singulation line portion (separation groove) in FIG. 10.

FIG. 12 is a diagram showing an example of a further enlarged view of the boundary portion between the singulation line portion and the glass substrate in FIG. 11.

FIG. 13 is a diagram showing another example of a further enlarged view of the boundary portion between the singulation line portion and the glass substrate in FIG. 11.

FIG. 14 is a diagram showing a case where the separation groove electrode is not formed on the side surface portion of the glass substrate.

FIG. 15 is a cross-sectional view illustrating the step of peeling the second support in the manufacturing method according to the first embodiment.

FIG. 16 is a cross-sectional view illustrating the state after the step of peeling the second support has been performed in the manufacturing method according to the first embodiment.

FIG. 17 is a cross-sectional view illustrating the step of forming the build-up layer in the manufacturing method according to the first embodiment.

FIG. 18 is a cross-sectional view illustrating the step of forming the connection pads in the manufacturing method according to the first embodiment.

FIG. 19 is a perspective view of the structure shown in FIG. 18.

FIG. 20 is a cross-sectional view illustrating the singulation step in the manufacturing method according to the first embodiment.

FIG. 21 illustrates a flowchart of the manufacturing method according to the first embodiment.

FIG. 22 is a cross-sectional view illustrating the step of forming the first wiring layer in the manufacturing method according to the first modification.

FIG. 23 is a cross-sectional view illustrating the step of forming laser-modified portions in the manufacturing method according to the first modification.

FIG. 24 illustrates a flowchart of a manufacturing method according to the first modification.

FIG. 25 is a cross-sectional view illustrating the step of bonding the second support in the manufacturing method according to the second modification.

FIG. 26 is a cross-sectional view illustrating the step of forming laser-modified portions in the manufacturing method according to the second modification.

FIG. 27 illustrates a flowchart of a manufacturing method according to the second modification.

FIGS. 28A, 28B, 28C, 28D, 28E, 28F and 28G show enlarged views illustrating a boundary portion between the singulation line portion and the glass substrate for each of the prepared samples (Examples 1 to 5) and Comparative Examples 1 and 2.

### DETAILED DESCRIPTION

Embodiments of the present disclosure will be described below with reference to the drawings.

It should be noted that the description below relates to examples of the present disclosure, and the disclosure is not limited by these examples. In the following description of the drawings, components identical with each other are given the same reference signs.

The position, size, shape, extent, and the like of each component shown in the drawings may not represent their actual position, size, shape, extent, and the like to facilitate understanding of the disclosure. Therefore, the present disclosure is not necessarily limited to the positions, sizes, shapes, extent, and the like shown in the drawings.

In the present disclosure, “surface” may refer not only to a surface of a plate-like member but also to the interface of a layer included in the plate-like member that is substantially parallel to a surface of the plate-like member. Furthermore, when a plate-like member or a layer included in the plate-like member is illustrated, “upper surface” and “lower surface” refer to surfaces illustrated on the upper and lower sides, respectively, in the drawing. The “upper surface” and “lower surface” may also be referred to as “first surface” and “second surface.”

Furthermore, “side surface” refers to the surface or layer thickness portion of a plate-like member or a layer in the plate-like member. A portion of a surface and a side surface together may be referred to as an “edge portion.”

The term “upper side” refers to a vertically upward direction when a plate-like member or a layer is placed horizontally. Additionally, “upper side” and the opposite direction, “lower side,” may be referred to as the “positive z-axis direction” and the “negative z-axis direction,” respectively. For horizontal directions, they may be referred to as an “x-axis direction” or a “y-axis direction.”

Additionally, “bottom” may refer to a portion in a direction perpendicular to the plane of the drawing.

### First Embodiment

### (Structure of Multilayer Wiring Board)

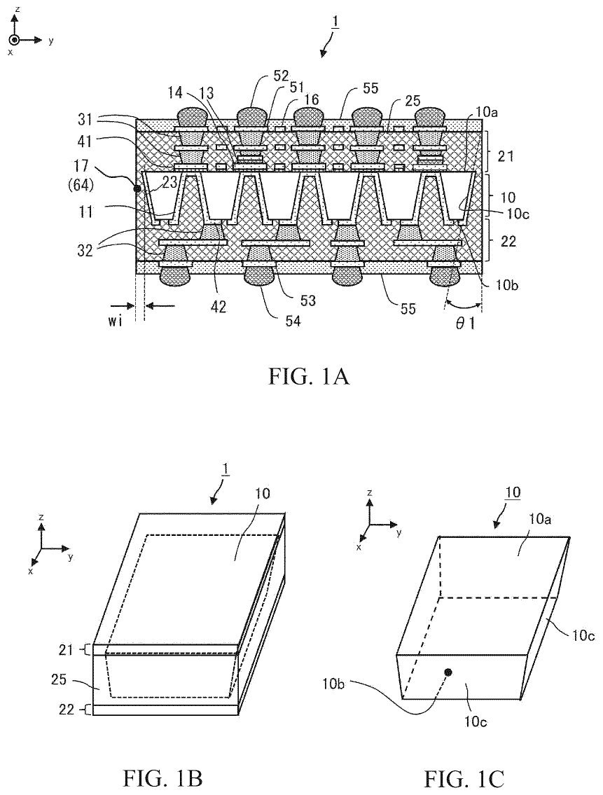

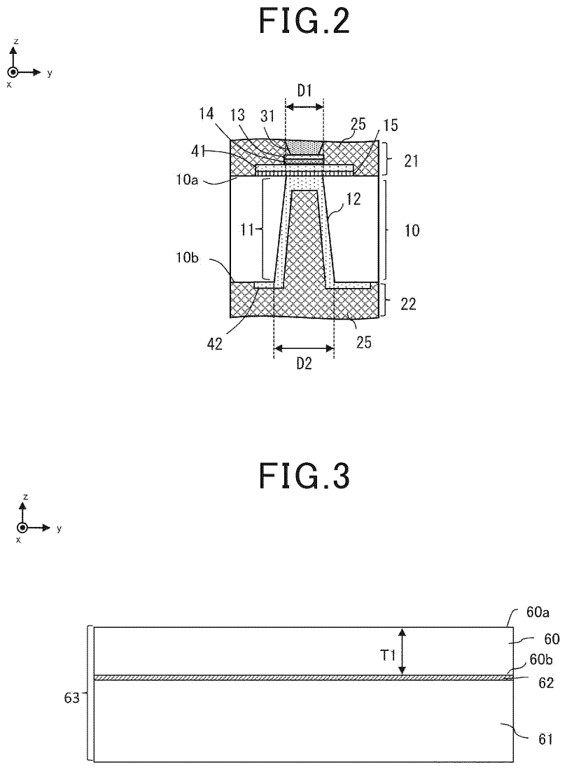

Referring to FIGS. 1 and 2, a multilayer wiring board according to the first embodiment will be described. FIG. 1 is a diagram illustrating a multilayer wiring board according to the first embodiment. FIG. 1A shows a cross-sectional view of the multilayer wiring board, and FIG. 1B shows a perspective view of the multilayer wiring board, and FIG. 1C shows a perspective view of a core substrate 10 included in the multilayer wiring board. FIGS. 1B and 1C schematically illustrate the outlines of the core substrate 10, a first wiring layer 21, a second wiring layer 22, and an insulating resin layer 25 for ease of understanding. FIG. 2 is a cross-sectional view illustrating an enlarged view of the structure of a through-electrode in a multilayer wiring board 1 according to the first embodiment. As shown in FIGS. 1 and 2, a multilayer wiring board 1 includes a core substrate 10 made of glass material. As shown in FIG. 1B, the core substrate 10 is surrounded by a resin member of the insulating resin layer 25 in the x-axis and γ-axis directions, and is surrounded by the first and second wiring layers 21 and 22 in the z-axis direction. The core substrate 10 has the first wiring layer 21 formed on its upper surface in the positive z-axis direction, hereinafter also referred to as “first surface 10a”, and the second wiring layer 22 formed on its lower surface in the negative z-axis direction, hereinafter also referred to as “second surface 10b”.

As shown in FIG. 1C, in addition to the first surface 10a and the second surface 10b opposing the first surface 10a, the core substrate 10 has a side surface portion 10c consisting of four faces connecting the peripheral portion of the first surface 10a and the peripheral portion of the second surface 10b. In the example of FIG. 1C, the core substrate 10 has a truncated square pyramid shape that tapers toward the negative z-axis direction, in which the first and second surfaces 10a and 10b are parallel to each other, and the core substrate 10 is surrounded by the side surface portion 10c consisting of four faces connecting the outer periphery or peripheral portion of the first surface 10a and the outer periphery (peripheral portion) of the second surface 10b. In FIG. 1C, the side surface portion 10c is depicted as a flat surface. However, since the side surface portion 10c also includes portions formed by etching for separation grooves 17 described later, the side surface portion 10c includes portions that are not flat. The core substrate 10 is formed with through-holes 11 extending from the first surface 10a to the second surface 10b, in other words, extending between the front and back surfaces. A seed layer or seed metal layer is formed on the inner wall surface of the through-hole 11, thereby forming a through-electrode 12 that electrically connects the first surface 10a side and the second surface 10b side of the core substrate 10. Furthermore, as shown in FIG. 2, a capacitor electrode 13 is disposed on the upper side of the through-electrode 12 in the first wiring layer 21. It is also possible to embed circuit elements other than capacitors, such as inductors, within the first wiring layer 21.

Next, with reference to FIG. 2, the configuration of the first wiring layer 21, which is a wiring layer formed on the first surface 10a of the core substrate 10, will be described. A through-electrode connection portion 41, hereinafter also referred to as a “first conductive portion”, is an electrode disposed within the first wiring layer 21 and connected to the through-electrode 12 via a hydrofluoric acid-resistant metal layer 15. A dielectric layer 14, a capacitor electrode 13, and a conductive electrode 31 are provided on the through-electrode connection portion 41. The capacitor electrode 13, dielectric layer 14, through-electrode connection portion 41, and the hydrofluoric acid-resistant metal layer 15 form a metal-insulator-metal (MIM) structure. Furthermore, wiring 16 (see FIG. 1A) is wiring disposed within the first wiring layer 21 and is connected to the through-electrode 12, the conductive electrode 31, and the like. The through-electrode connection portion 41, the conductive electrode 31, the capacitor electrode 13, the dielectric layer 14, and the wiring 16 are all protected by an insulating resin layer 25. Furthermore, as shown in FIG. 1, when the multilayer wiring board 1 is used as an intermediary substrate for connecting a plurality of semiconductor devices, that is, as an interposer substrate, semiconductor-device bonding pads 51 are bumps used when mounting another semiconductor device or connecting to another semiconductor device. A solder resist 55 is a film made of an insulating member for protecting the multilayer wiring board 1. Here, two conductive electrodes 31 are stacked within the first wiring layer 21. This indicates that the first wiring layer 21 is formed by stacking two wiring layers.

Next, with reference to FIG. 2, the configuration of the second wiring layer 22, which is a wiring layer formed on the second surface 10b of the core substrate 10, will be described. A through-electrode connection portion 42, hereinafter also referred to as a “second conductive portion”, is an electrode disposed within the second wiring layer 22 and connected to the through-electrode 12, and is formed to match the shape of the open end of the through-electrode 12. A conductive electrode 32 (see FIG. 1A) is connected to the through-electrode connection portion 42. The through-electrode connection portion 42 disposed in the second wiring layer 22 and the through-electrode connection portion 41 disposed in the first wiring layer 21 are electrically connected to each other through the through-electrode 12. Board bonding solder 54 is a bump used for connection to a printed wiring board. Note that, as shown in FIG. 1, the solder resist 55 is a film made of an insulating member for protecting the multilayer wiring board 1. Here, the conductive electrode 32 forms a conductive path within the second wiring layer 22 by being stacked or through another wiring layer. This indicates that the second wiring layer 22 is formed by stacking two wiring layers.

Next, the remaining components of the multilayer wiring board will be described with reference to FIG. 1A. Since the first and second wiring layers 21 and 22 include the insulating resin layer 25, the side surface portion 10c of the core substrate 10 is covered by the same type of insulating resin as that forming the insulating resin layer 25. A separation-groove electrode 23 is formed on the side surface portion 10c so as to cover the side surface portion 10c. The separation-groove electrode 23 is made of a metal layer, similarly to the through-electrode 12. In the example shown in FIG. 1A, the side surface portion 10c is covered with at least a metal member and an insulating resin. Although FIG. 1A shows a case where the entire side surface portion 10c of the core substrate 10 is covered with the separation-groove electrode 23, the present disclosure is not limited to this case. It is preferable that 10% or more of the side surface portion 10c of the core substrate 10 be covered with a metal member.

### (Dimensions and Composition of Multilayer Wiring Board)

The ratio of an opening diameter D1 on the first surface 10a side to an opening diameter D2 on the second surface 10b side of the through-electrode 12 (first-surface-side opening diameter D1/second-surface-side opening diameter D2) is preferably in the range of 0.35 or more and 0.65 or less (i.e., 0.35 to 0.65). By making the opening diameter on the first surface 10a side smaller than the opening diameter on the second surface 10b side, the capacitor electrode 13 can be stably formed on the through-electrode 12.

The thickness of the core substrate 10 is preferably within the range of 50 μm or more and 150 μm or less (i.e., 50 μm to 150 μm), and can be set in accordance with characteristic values of the capacitor electrode 13, an inductor, a resistor, or the like formed in the first wiring layer 21. When the thickness of the core substrate 10 is greater than 150 μm, the ratio of the opening diameter D1 on the first surface 10a side to the opening diameter D2 on the second surface 10b side (first-surface-side opening diameter D1/second-surface-side opening diameter D2) becomes smaller than 0.35, making it difficult to form the capacitor electrode 13 on the through-electrode 12 and to ensure connection reliability of the through-electrode 12. More preferably, the thickness of the core substrate 10 is within the range of 100 μm or more and 150 μm or less (i.e., 100 μm to 150 μm). The thickness of the core substrate will be described later with reference to FIG. 9, where the thickness is denoted by T2.

The ratio of the opening diameter D1 on the first surface 10a side to the opening diameter D2 on the second surface 10b side may be set as appropriate as long as it is within the above range.

The insulating resin layer 25 preferably has a relative permittivity of 3.1 or more and 3.5 or less (i.e., 3.1 to 3.5) and a dielectric loss tangent of 0.002 or more and 0.012 or less (i.e., 0.002 to 0.012). Such an insulating resin layer 25 can be formed of a thermosetting resin.

Examples of the thermosetting resin include an epoxy resin, a polyimide resin, a polyamide resin, and composite materials thereof, in which a filler material containing at least SiO₂ as a component is loaded in the range of 65% or more and 80% or less (i.e., 65% to 80%). If the filling ratio of the SiO₂ filler material is 65% or less, the relative permittivity and the dielectric loss tangent are outside the above ranges, which may deteriorate transmission characteristics. Therefore, the filling ratio of the SiO₂ filler material is preferably 72% or more.

Among the above composite materials, a material highly loaded with the SiO₂ filler material results in an insulating resin with a low linear expansion coefficient that is close to that of a glass material. Accordingly, by using such a material, it is possible to reduce the stress that may occur when a wiring layer is formed on the core substrate 10. This allows the relative permittivity and dielectric loss tangent to be within the above ranges, thereby avoiding adverse effects on transmission characteristics.

On the side surface of the multilayer wiring board 1, a portion of the insulating resin layer 25 in the first and second wiring layers 21 and 22, as well as a portion of the insulating resin formed on the side surface portion 10c of the core substrate 10 are exposed. For example, a thickness wi (see FIG. 1A) of the insulating resin on the side surface portion of the multilayer wiring board 1 is preferably at least 50 μm or more when measured in the x- or y-axis direction. Furthermore, when the angle between the z-axis direction and the side surface is denoted as θ1, it is preferable that the side surface portion 10c of the core substrate 10 reaches the second wiring layer 22 at an angle θ1 in the range of 21° or more and 35° or less (i.e., 21° to) 35° with reference to the edge portion of the first wiring layer 21 of the core substrate 10.

The side surface portion 10c of the core substrate 10 (the side surface of the multilayer wiring board 1) is covered with an insulating resin material. As a result, the side surface of the multilayer wiring board is entirely protected by the insulating resin material in the x- and y-axis directions. This makes it possible to distribute stress generated in the first wiring layer 21 or the second wiring layer 22 formed on the upper and lower surfaces of the core substrate 10, respectively, to the other wiring layer through the insulating resin at the side surface of the core substrate 10. Furthermore, it is possible to suppress the occurrence of μ-cracks and chipping at the edge portions of the core substrate 10, thereby improving the reliability of the multilayer wiring board 1.

The capacitors formed in the first wiring layer 21 of the multilayer wiring board 1 have a MIM structure. From the perspectives of insulation properties and relative permittivity, at least one of alumina, silica, silicon nitride, tantalum oxide, titanium oxide, calcium titanate, barium titanate, and strontium titanate may be selected for the dielectric layer 14 forming the capacitors. Materials used for the upper and lower electrodes of the MIM structure may include, for example, at least one of Cu, Ni, Al, Ti, Cr, Mo, W, Ta, Au, Ir, Ru, Pd, Pt, AlSi, AlSiCu, AlCu, and NiFe. For example, Cu is a preferred material.

The core substrate 10 used in the multilayer wiring board 1 may be a transparent glass material that transmits light. The glass may have any components or any mixing ratio of the contained components, and may also be produced by any method. For example, the glass may be non-alkali glass, alkali glass, borosilicate glass, quartz glass, sapphire glass, photosensitive glass, or the like. Any glass material containing silicate as a main component may be used. Other glass materials may also be used. However, in the multilayer wiring board according to the present embodiment, non-alkali glass is preferably used.

The core substrate 10 may employ glass produced by, for example, a float process, a down-draw process, a fusion process, an up-draw process, or a roll-out process. However, a glass material produced by any method may be used. The glass preferably has a linear expansion coefficient within the range of −1 ppm/K or more and 15.0 ppm/K or less (i.e., −1 ppm/K to 15.0 ppm/K). One reason for this is that if the coefficient is-1 ppm/K or less, it is difficult to select an appropriate glass material. On the other hand, if the coefficient is 15.0 ppm/K or more, the difference in thermal expansion coefficient relative to the other layers becomes large, which may reduce reliability when the glass is used in a multilayer wiring board. Moreover, when a silicon chip is mounted on the multilayer wiring board 1 of the present embodiment, the connection reliability with the silicon chip may be reduced. The linear expansion coefficient of the glass is more preferably within the range of 0.5 ppm/K or more and 8.0 ppm/K or less (i.e., 0.5 ppm/K to 8.0 ppm/K), and even more preferably within the range of 1.0 ppm/K or more and 4.0 ppm/K or less (i.e., 1.0 ppm/K to 4.0 ppm/K).

### First Manufacturing Method According to an Embodiment of the Present Disclosure

A method for manufacturing the multilayer wiring board 1 in the first embodiment will be described below with reference to FIGS. 3 to 15. In the drawings described below, for ease of understanding, a portion of a glass substrate described later that includes one multilayer wiring board 1 is extracted and illustrated. A plurality of similar portions are arranged in the xy-plane direction of the glass substrate to form a multilayer wiring base substrate.

### (Bonding of First Support)

First, with reference to FIG. 3, a step of bonding a first support 61 to a glass substrate 60, which is a base substrate, will be described. FIG. 3 is a cross-sectional view illustrating the bonding step of the first support 61 in the manufacturing method according to the first embodiment.

The glass substrate 60 has a first surface 60a and a second surface 60b. As shown here, the first support 61 is bonded to the glass substrate 60 using a first adhesive layer 62, forming a laminated structure 63 consisting of the glass substrate 60, the first adhesive layer 62, and the first support 61.

Note that, since the first adhesive layer is very thin compared to the glass substrate 60 and the first support 61, the first adhesive layer could be described as an interface between the glass substrate 60 and the first support 61. However, in the drawings of the present disclosure, it is illustrated as a layer having a thickness for visibility. Furthermore, while the glass substrate 60 extends in the y-axis direction, the drawings show only a portion thereof, and therefore its edge portions in the x-axis direction and the y-axis direction are illustrated as straight lines.

The first adhesive layer 62 is an adhesive layer for temporarily fixing the first support 61 to the glass substrate 60. The first adhesive layer 62 is a surface that contains hydroxyl groups and is formed on the second surface 60b of the glass substrate 60. The composition of the adhesive interface may contain a plurality of other functional groups as long as it contains hydroxyl groups. Therefore, the material of the first adhesive layer 62 may be appropriately selected from resins that become detachable by absorbing light such as UV light and undergoing heat generation, sublimation, or degradation; resins that become detachable by heat-induced foaming; and functional groups.

To bond the first support 61 to the glass substrate 60, for example, a laminator, a vacuum pressure press, or a reduced-pressure bonding apparatus can be used.

Thus, by forming an interface containing hydroxyl groups on the second surface 60b of the glass substrate 60, it becomes possible to form hydrogen bonds using the hydroxyl groups between the glass substrate 60 and the first support 61. The adhesive layer containing hydroxyl groups may also be formed on the first surface 60a of the glass substrate 60.

It is preferable that the first support 61 be made of the same material as the glass substrate 60. When the glass substrate 60 is made of alkali-free glass, it is preferable that the first support 61 also be made of alkali-free glass. The thickness of the first support 61 can be appropriately set according to a thickness T1 of the glass substrate 60. However, it is preferable that the thickness be such that transport is possible during the manufacturing process. For example, the thickness T1 of the glass substrate 60 is in the range of 75 μm or more and 200 μm or less (i.e., 75 μm to 200 μm), and the thickness of the first support 61 can be set in the range of 300 μm or more and 1,500 μm or less (i.e., 300 μm to 1,500 μm).

In this embodiment, the first support 61 is made of a glass material and utilizes hydroxyl groups as well as a plurality of functional groups as the adhesive interface.

The adhesion strength between the glass substrate 60 and the first support 61 is preferably in the range of 0.15 J/cm² or more and 0.45 J/cm² or less. When a strength within the above range cannot be obtained, annealing may be performed after formation of the hydroxyl groups to improve the adhesion strength. If the adhesion strength is 0.15 J/cm² or less, there is a high possibility of delamination at the interface between the glass substrate 60 and the first support 61 during process flow. On the other hand, when the adhesion strength is 0.45 J/cm² or more, problems are likely to occur during the peeling step described elsewhere. More preferably, the adhesion strength is in the range of 0.25 J/cm² or more and 0.4 J/cm² or less (i.e., 0.25 J/cm² to 0.4 J/cm²). Although the adhesion strength was measured using the crack opening method, the measurement method is not limited to this.

### (Formation of Laser-Modified Portions)

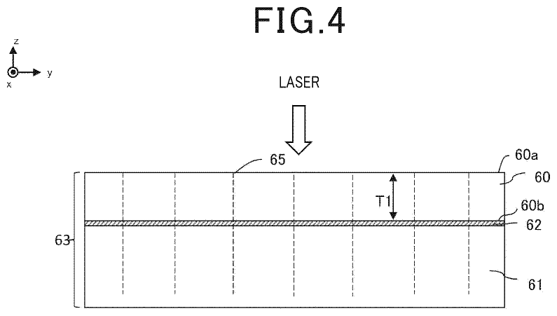

Next, a step of forming laser-modified portions will be described with reference to FIG. 4. FIG. 4 is a cross-sectional view illustrating the step of forming the laser-modified portions in the manufacturing method according to the first embodiment. In FIG. 4, the broken lines indicate laser-modified portions 65. As shown in FIG. 4, the laminated structure 63 is irradiated with laser light from the first surface 60a side to form the laser-modified portions 65. The laser-modified portions 65 extend, for example, in a direction perpendicular to the glass substrate 60 and can be formed at desired positions over substantially the entire surface of the glass substrate 60. In this case, the laser-modified portions 65 may be formed so as to reach the first adhesive layer 62 and the first support 61.

In this embodiment, by performing laser irradiation with the first support 61 stacked on the glass substrate 60, it is possible to widen the process window for the laser irradiation and to form the laser-modified portions 65 at desired positions on the glass substrate 60.

When an adhesive layer made of resin is used as the first adhesive layer 62, laser irradiation may generate cracks in the resin in the adhesive, resulting in adhesive resin to remain on the glass substrate 60 when removing the first support 61 from the glass substrate 60. When such adhesive resin remains on the glass substrate 60, it may cause defects in the subsequent through-hole formation step by hydrofluoric acid etching. For example, it may lead to the occurrence of surface irregularities on the glass substrate 60. Therefore, to bond the glass substrate 60 and the first support 61, it is preferable to use an interface containing hydroxyl groups rather than a resin adhesive layer.

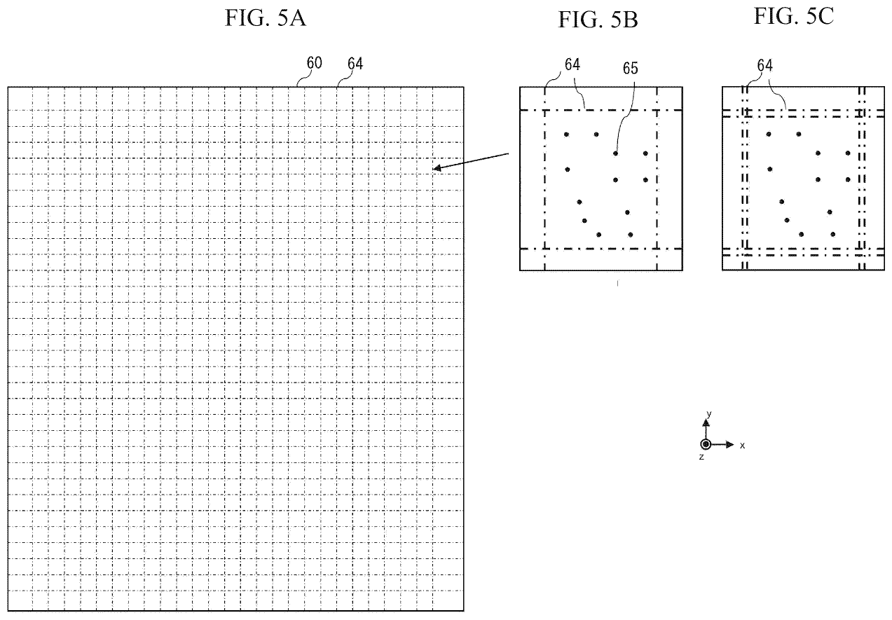

FIG. 5 is a diagram illustrating singulation lines 64, which correspond to the locations where the laser-modified portions are formed, and the laser-modified portions 65, which serve as the through-hole formation portions in the multilayer wiring board, in the manufacturing method according to the first embodiment. FIG. 5A is a plan view of the glass substrate 60 as seen from the positive z-axis direction and FIG. 5B is an exemplary enlarged view of a portion of the glass substrate 60. Here, the dot-dashed lines indicate the singulation lines 64. The singulation lines are the positions where separation grooves are formed when separating multilayer wiring boards from the glass substrate 60, and laser-modified portions are also formed at these positions where the separation grooves are formed. Furthermore, each laser-modified portion 65 within the multilayer wiring board is a position serving as a starting point of the through-hole 11 and is indicated by a black dot. In other words, laser modification is applied at locations where the through-holes 11 or separation grooves are to be formed.

FIG. 5C shows another example of an enlarged view of a portion of the glass substrate in a different example. As illustrated here, in a case where the laser-modified portions are formed along the separation grooves, a plurality of laser-modified portions may be formed by shifting the laser irradiation position to provide the singulation lines 64.

### (Formation of First Wiring Layer)

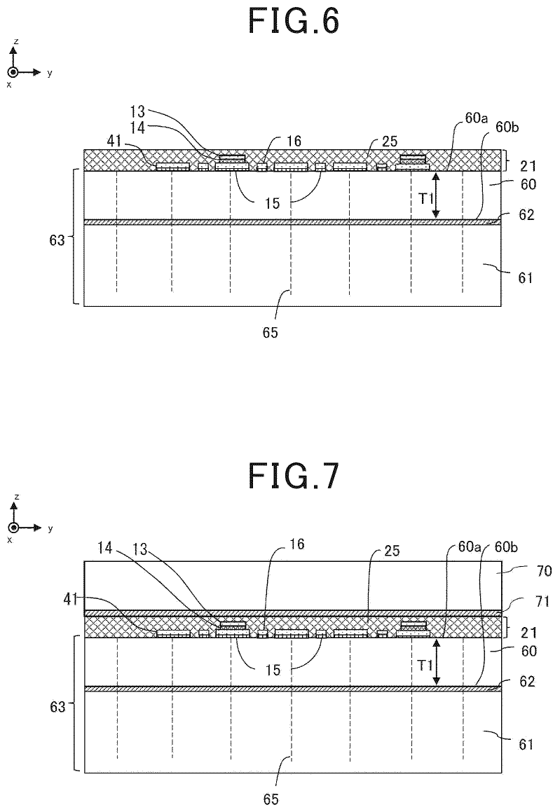

Next, a step of forming the first wiring layer 21 will be described with reference to FIG. 6. FIG. 6 is a cross-sectional view illustrating the step of forming the first wiring layer in the manufacturing method according to the first embodiment. As shown here, the first wiring layer 21 including a conductive layer and an insulating layer is formed on the first surface 60a of the glass substrate 60 in the laminated structure 63.

First, a seed layer including a hydrofluoric acid-resistant metal layer 15 is formed on the glass substrate 60. The hydrofluoric acid-resistant metal layer 15 on the glass substrate 60 is an alloy layer containing at least one of chromium or nickel, and is formed by sputtering to a thickness in the range of 10 nm or more and 1,000 nm or less (i.e., 10 nm to 1,000 nm). After that, a conductive metal film is formed on the hydrofluoric acid-resistant metal layer 15 to a desired thickness. The material of the conductive metal film may be appropriately selected from, for example, Cu, Ni, Al, Ti, Cr, Mo, W, Ta, Au, Ir, Ru, Pd, Pt, AlSi, AlSiCu, AlCu, NiFe, ITO, IZO, AZO, ZnO, PZT, TiN, and Cu₃N₄.

The electrode connection portions (electrode) and the wiring may be formed, for example, by a semi-additive process (SAP). In the semi-additive process, a photoresist is used to form a desired pattern. In general, a dry film resist is used, but a liquid resist may also be used. After exposure and development of the resist to form a desired pattern, an electroplated film having a thickness of 2 μm or more and 20 μm or less (i.e., 2 μm to 20 μm) is formed. The resist pattern no longer needed is removed and the seed layer is etched to form the through-electrode connection portions 41 above the laser-modified portions and the wiring 16 located between the laser-modified portions 65.

From the perspectives of insulation properties and relative permittivity, the dielectric layer 14 on the through-electrode connection portion 41 is formed using at least one of alumina, silica, silicon nitride, tantalum oxide, titanium oxide, calcium titanate, barium titanate, and strontium titanate. The dielectric layer 14 preferably has a thickness in the range of 10 nm or more and 5 μm or less (i.e., 10 nm to 5 μm). If the thickness of the dielectric layer 14 is 10 nm or less, sufficient insulation may not be maintained and the capacitor may not function properly. If the dielectric layer 14 has a thickness of 5 μm or more, not only does the film formation take too long, resulting in poor suitability for mass production, but also the step of removing unnecessary portions may require additional time. Therefore, the thickness of the dielectric layer 14 is more preferably in the range of 50 nm or more and 1 μm or less (i.e., 50 nm to 1 μm).

The capacitor electrode 13 is formed by separately forming a lower electrode layer and an upper electrode layer. The lower electrode layer may be formed using at least one of Cu, Ni, Al, Cr, Mo, W, Ta, Au, Ir, Ru, Pd, Pt, AlSi, AlSiCu, AlCu, and NiFe as a material, from the perspectives of adhesion and electrical conductivity. For example, Ti is superior from the perspectives of adhesion, electrical conductivity, ease of production, and cost.

A seed metal layer is formed for the upper electrode of the capacitor electrode 13, and an electroplated layer is further formed. For the seed metal layer, at least one of Cu, Ni, Al, Ti, Cr, Mo, W, Ta, Au, Ir, Ru, Pd, Pt, AlSi, AlSiCu, AlCu, NiFe, and Cu may be used. It is preferable to use copper to facilitate etching removal later. The seed metal layer preferably has a thickness in the range of 10 nm or more and 5 μm or less (i.e., 10 nm to 5 μm). If the seed metal layer has a thickness of less than 100 nm, energization failure may occur during the subsequent electroplating. If the seed metal layer has a thickness exceeding 5 μm, the time taken for etching removal may be long. Therefore, the thickness of the seed metal layer is more preferably in the range of 100 nm or more and 500 nm or less (i.e., 100 nm to 500 nm).

Then, an electroplated layer is formed as the upper electrode of the capacitor electrode 13. Copper electroplating is simple and inexpensive and provides good electrical conductivity. Besides copper electroplating, electroplating of nickel, chromium, Pd, gold, rhodium, iridium, or the like may be used. After formation of the upper electrode, the seed metal layer is removed. Wet etching, dry etching, or the like may be selected as the removal method as appropriate depending on the application.

Regarding the formation of the capacitor electrodes 13, in conventional manufacturing methods for producing a multilayer wiring board using a substrate in which the through-holes 11 are formed in advance, a conductive material cannot be deposited over the through-holes, and thus MIM structures have to be formed so as to avoid the through-holes. In contrast, according to the manufacturing method of the present embodiment, since the wiring formation step and the capacitor electrode formation step are performed before the through-hole formation step, the capacitor electrodes 13 can be formed near through-holes and above through-holes, that is, without being restricted by the through-holes' positions. For example, it is also possible to provide the capacitor electrodes 13 directly above the through-holes. This allows the transmission distance to the capacitor to be shortened, thereby avoiding degradation of transmission characteristics. Furthermore, by forming a lower electrode layer when forming the capacitor electrodes 13, it is possible to reduce variation in the capacitance of the capacitors.

Finally, the insulating resin layer 25 is formed. The insulating resin layer 25 is made of a thermosetting resin, and the material therefor preferably includes at least one of an epoxy resin, a polyimide resin, and a polyamide resin, includes an SiO₂ filler material, and is in a liquid form or a film form. For a liquid resin, the insulating layer can be formed by spin coating, and for a film-type resin, the insulating layer can be formed by heating and pressurizing under vacuum using a vacuum laminator. The material of the insulating resin layer 25 may be selected as appropriate depending on need. However, since filling with an SiO₂ filler material becomes difficult when using a photosensitive insulating resin material due to the need to ensure photolithography properties, the material is limited to non-photosensitive thermosetting resin.

### (Bonding of Second Support)

Next, a bonding step of a second support will be described with reference to FIG. 7. FIG. 7 is a cross-sectional view illustrating the bonding step of the second support in the manufacturing method according to the first embodiment. As shown herein, a second adhesive layer 71 can be formed on the first wiring layer 21 of the laminated structure 63, and a second support 70 can be bonded to the second adhesive layer 71.

As with the first adhesive layer 62, the material of the second adhesive layer 71 can be appropriately selected from resins that become detachable by absorbing light such as UV light and undergoing heat generation, sublimation, or degradation; resins that become detachable by heat-induced foaming; and functional groups that temporarily fix the glass substrate 60 and the first support 61. The second adhesive layer 71 is preferably formed of a material different from that of the first adhesive layer 62.

The second support 70 may be made of the same material as the glass substrate 60. When the glass substrate 60 is alkali-free glass, the first support 61 also may be alkali-free glass. The thickness of the second support can be appropriately set according to the thickness of the glass substrate 60. However, the thickness is preferably such that the substrate is transportable, and is preferably in the range of 300 μm or more and 1,500 μm or less (i.e., 300 μm to 1,500 μm).

### (Removal of First Support)

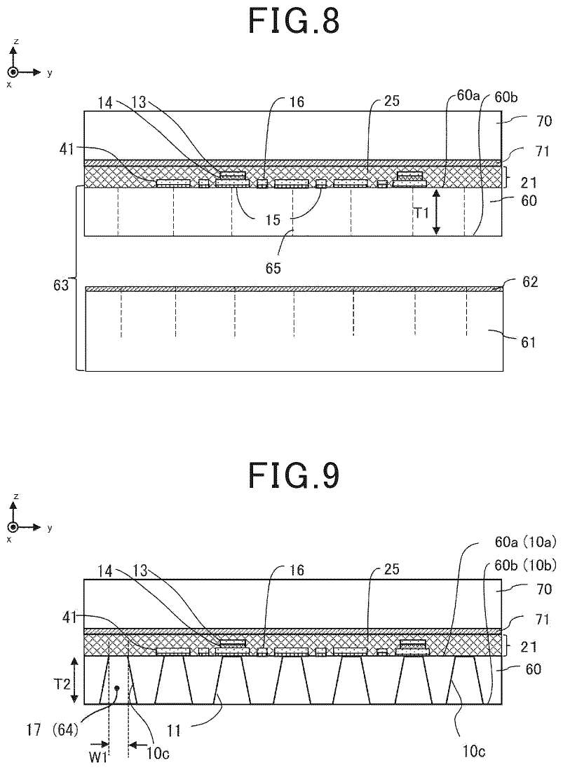

Next, a removal step of the first support will be described with reference to FIG. 8. FIG. 8 is a cross-sectional view illustrating the removal step of the first support 61 in the manufacturing method according to the first embodiment. As shown here, the glass substrate 60 and the first adhesive layer 62 can be delaminated at their interface to separate the first adhesive layer 62 and the first support 61 from the glass substrate 60.

To separate the first support 61 from the glass substrate 60, a physical force is applied to a side surface of the first adhesive layer 62 to form a delamination initiation portion, and by applying force starting from this delamination initiation portion, the interface of the first adhesive layer 62 can be delaminated.

More specifically, a portion of a side surface of the first adhesive layer 62 where scoring was performed using a cutter or the like serves as the peeling initiation point, and the glass substrate 60 and the first support 61 can be separated by applying a force in a direction separating the first support 61 and the glass substrate.

The peeling process can be carried out smoothly by performing the scoring while applying a force so as to separate the first support 61 and the glass substrate. An appropriate peeling method may be selected from among UV light irradiation, heat treatment, physical peeling, and the like, according to the material used for the first adhesive layer 62. If residue of the first adhesive layer 62 remains on the glass substrate 60, plasma cleaning, ultrasonic cleaning, water washing, or solvent cleaning using alcohol may be performed.

### (Formation of Through-Holes by Etching)

Next, a step of forming through-holes by etching will be described with reference to FIG. 9. FIG. 9 is a cross-sectional view illustrating the step of forming the through-holes by etching in the manufacturing method according to the first embodiment. FIG. 9 illustrates the shape of the glass substrate 60 after hydrofluoric-acid etching. The through-holes 11 and the separation grooves 17 are simultaneously formed by hydrofluoric acid etching. In the separation grooves 17, the insulating resin layer 25 is exposed when viewed from the negative z-axis direction. In other words, by selectively removing the laser-modified portions 65 by etching from the second surface 60b side of the glass substrate 60, the through-holes 11 and the separation grooves 17 are formed, and the separation grooves 17 divide the glass substrate 60 into individual multilayer wiring boards. However, the glass substrate 60 remains held together by the second support 70 and the first wiring layer. Therefore, as shown in FIG. 5A, even though the singulation lines 64 are formed, it maintains integrity as a multilayer wiring base substrate. In the following description, the separation grooves 17 may also be referred to as the singulation lines 64.

Wet etching using an aqueous hydrofluoric acid solution is suitable for the etching. The amount of etching by the aqueous hydrofluoric acid solution is determined as appropriate according to the thickness of the glass multilayer wiring board. For example, if the thickness T1 of the glass substrate 60 is 200 μm, the amount of etching is preferably 50 μm or more and 175 μm or less (i.e., 50 μm to 175 μm). Here, a structure in which the insulating resin layer 25 is exposed when the separation grooves 17 are viewed from the negative z-axis direction is shown, but the structure is not limited to this. If a seed layer including the hydrofluoric acid-resistant metal layer 15 of the first wiring layer 27 is left in the separation grooves 17, the seed layer of the first wiring layer 27 may remain on the singulation lines 64.

Note that as the laser-modified portions 65 are etched, the thickness of the glass substrate 60 in the z-axis direction is also etched. The thickness T2 of the glass substrate 60 after etching is preferably within the range of 25 μm or more and 150 μm or less (i.e., 25 μm to 150 μm). In conventional multilayer wiring boards, the thickness of the core substrate was generally 300 μm or more and 400 μm or less (i.e., 300 μm to 400 μm). Therefore, the first embodiment enables achieving a thinner core substrate than conventional ones and can suppress the impact on transmission characteristics.

The second surface 60b of the glass substrate 60 corresponds to the second surface 10b of the core substrate 10. Therefore, in the following description, it is also referred to as the second surface 10b of the glass substrate 60. Similarly, the first surface 60a of the glass substrate 60 also corresponds to the first surface 10a of the core substrate 10, and is therefore also referred to as the first surface 10a of the glass substrate 60. Furthermore, since the portions of the glass substrate 60 facing the separation grooves 17 become the side surface portion 10c of the core substrate 10 after singulation, they are denoted by the reference sign 10c.

### (Formation of Second Wiring Layer)

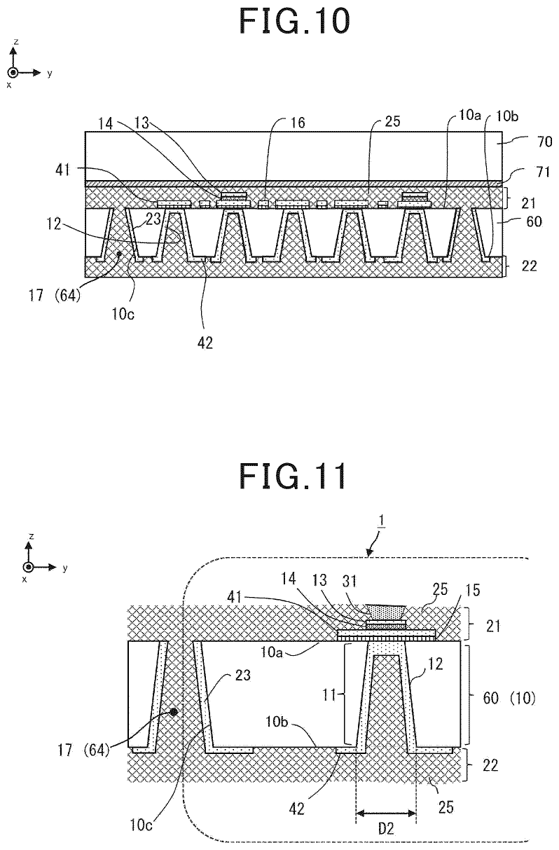

Next, a step of forming the second wiring layer and a step of forming a metal layer on the singulation line 64 portion will be described with reference to FIGS. 10 to 14. FIG. 10 is a cross-sectional view illustrating the step of forming the second wiring layer in the manufacturing method according to the first embodiment. The metal member of the side surface portion 10c of the core substrate 10 includes a film deposited by sputtering as a seed layer and a metal layer formed by plating. Specifically, as illustrated here, the second wiring layer 22 consisting of the through-electrode connection portions 42 and the insulating resin layer 25 is formed on the second surface 10b of the glass substrate 60. To form the through-electrodes 12 and the through-electrode connection portions 42, a seed layer for power supply is formed, a pattern is formed using a resist, hereinafter also referred to as “patterning”, and plating is performed to form a plating layer with a thickness of 2 μm or more and 20 μm or less (i.e., 2 μm to 20 μm). Subsequently, the resist pattern no longer needed is stripped, the seed layer is removed, and the through-electrodes 12 and the through-electrode connection portions 42 are formed.

Here, a separation groove electrode 23 is formed in the separation grooves 17. The separation groove electrode 23 will be described in detail with reference to FIGS. 11 to 14.

FIG. 11 is an enlarged view of the singulation line 64 portion or separation groove 17 of FIG. 10. The separation groove electrode 23 can be composed of a seed layer and a metal layer formed thereon by plating.

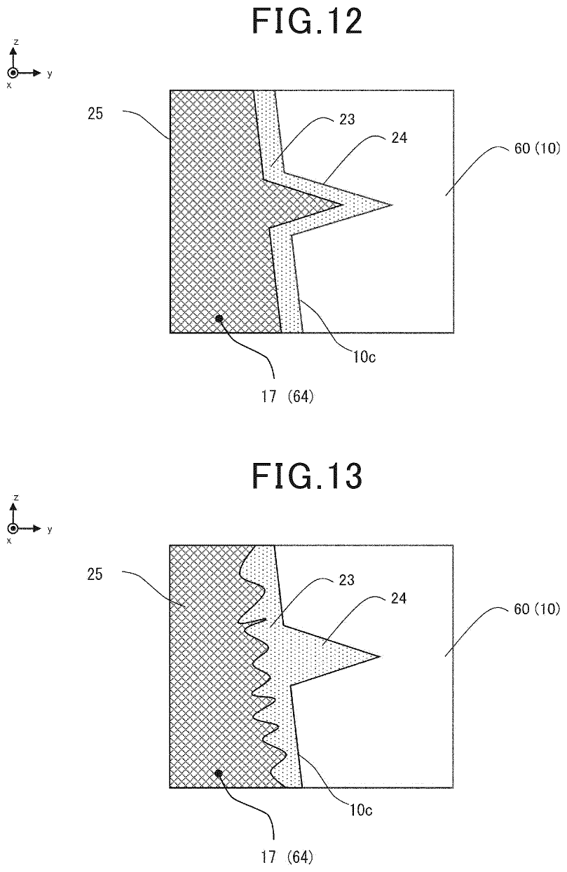

FIG. 12 is a diagram showing an example of a further enlarged view of the boundary portion between the singulation line 64 portion and the glass substrate 60 in FIG. 11. μ-cracks 24 caused by laser irradiation are present on the side surface portion 10c of the glass substrate 60. These μ-cracks 24 are also formed in the through-electrodes 12 and the separation grooves 17, and as shown in FIG. 12, they are covered by the metal layer of the separation groove electrode 23 or filled with the insulating resin layer 25.

This improves the adhesion between the insulating resin layer 25 described later and the glass substrate 60, thereby suppressing delamination and cracking of the glass substrate 60 or core substrate 10 due to stress.

FIG. 13 is a diagram showing another example of a further enlarged view of the boundary portion between the singulation line 64 portion and the glass substrate 60 in FIG. 11. By covering the side surface portion 10c of the glass substrate 60 with the metal member constituting the separation groove electrode 23, the metal member fills the μ-cracks 24. Furthermore, after the metal member is formed, an excess surface portion of the metal member is removed, thereby creating roughness on the surface of the metal member. This roughness further improves adhesion through an anchor effect when the insulating resin layer 25 is formed.

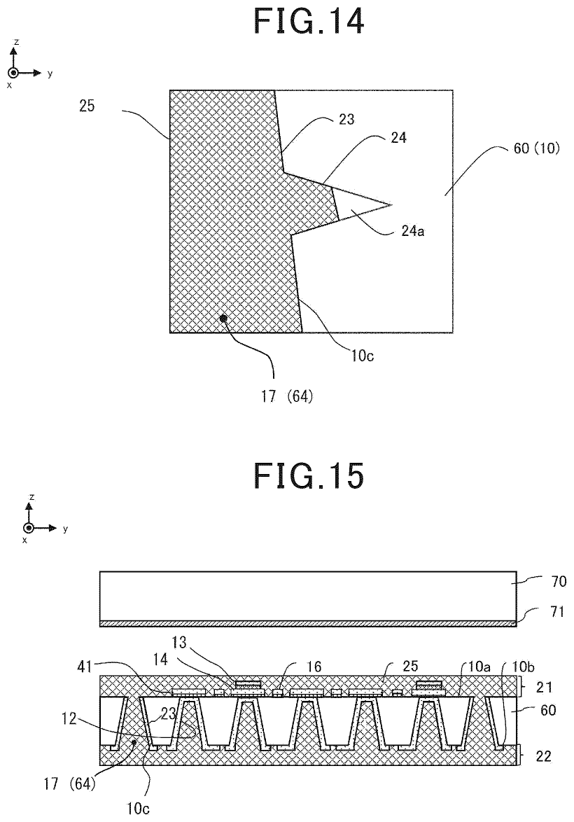

On the other hand, FIG. 14 is a diagram showing a case where the separation groove electrode 23 is not formed on the side surface portion 10c of the glass substrate 60. Since the resin of the insulating resin layer 25 is not embedded in the μ-crack 24 portion and a cavity 24a is formed, delamination may occur due to insufficient adhesion between the resin of the insulating resin layer 25 and the core substrate 10. Furthermore, if the insulating resin layer 25 contains filler, when the filler diameter is larger than the size of the μ-cracks 24, the filler may cap the μ-cracks 24 and prevent the resin from entering.

The patterning width on the side surface portion 10c of the glass substrate 60, i.e., the portion where the metal member is disposed, defines the size of the separation groove electrode 23, and it requires adjustment according to the processing width during singulation, e.g., a width corresponding to the blade width. The processing width during singulation must be smaller than the non-patterning width, i.e., the portion where the metal member is not disposed. For example, during blade dicing, it is preferable that the non-patterning width be sufficiently large relative to the blade width, which is the processing width. If the non-patterning width is smaller than the blade width, the processing portion of the blade may come into contact with the metal layer, causing damage to the blade. The same applies to processing by a laser or scribing, and therefore it is preferable to make adjustments so that the metal layer does not reach the cut surface.

After the through-electrodes 12, the through-electrode connection portions 41, and the separation groove electrode 23 are formed, the insulating resin layer 25 is formed to form the second wiring layer 22. The insulating resin layer 25 is also filled within the through-electrodes 12. Although the portions of the insulating resin layer 25 formed in the first wiring layer 21 and the second wiring layer 22 are assumed to be formed from the same material in the example shown here, it is not limited thereto, and they may be formed of different materials.

In a case where the insulating resin layer 25 is filled by lamination pressing using a sheet, pressing the μ-cracks 24 without forming a metal layer thereon may cause the cracks to expand. In the present disclosure, filling the μ-cracks with metal also has the effect of suppressing crack propagation. As a result of disposing the separation groove electrode 23 in the separation grooves 17 (singulation lines 64), the μ-cracks 24 are filled with a metal member. This prevents breakage of the glass substrate, avoids delamination between the resin and the core substrate, and thus prevents damage to the core substrate and ensures the reliability of the multilayer wiring board.

The second wiring layer 22 may be made of a material different from the hydrofluoric acid-resistant metal layer 15 because of the absence of etching using a hydrofluoric acid aqueous solution in the subsequent steps. In this case, the side surface of the through-hole 11 is provided with a metal layer made of a material different from that of the hydrofluoric acid-resistant metal layer 15 to form the through-electrode connection portion 42. Examples of materials different from the material of the hydrofluoric acid-resistant metal layer 15 include Ti and Cu, and at least one metal layer made of one or more of these materials is formed on the side surface of the through-hole 11 and on the second surface 10b of the glass substrate 60. The materials, number of layers, and the like are not limited to those disclosed in the embodiments and can be appropriately set as necessary.

### (Removal of Second Support)

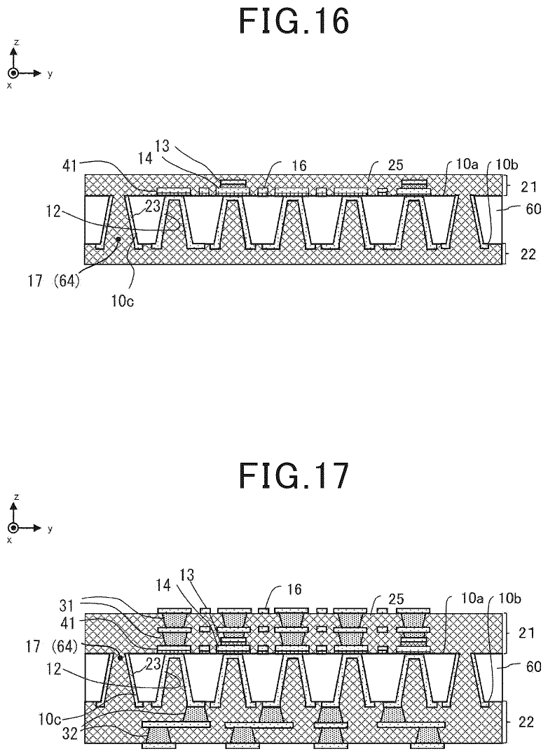

Next, a removal step of the second support 70 will be described with reference to FIGS. 15 and 16. FIG. 15 is a diagram illustrating the removal step of the second support 70 in the manufacturing method according to the first embodiment. FIG. 16 is a diagram showing the state after the step of peeling the second support 70 has been performed in the manufacturing method according to the embodiment of the present disclosure. As shown in FIG. 15, the first wiring layer 21 and the second support 70 are detached at their interface to remove the second support 70 and the second adhesive layer 71. As a result, as shown in FIG. 16, the glass substrate 60 is obtained in which the first wiring layer 21 is formed on the first surface 10a side of the glass substrate 60 and the second wiring layer 22 is formed on the second surface 10b side.

To separate the second support 70 from the second wiring layer 22, a peeling method can be selected from among UV light irradiation, heat treatment, physical peeling, and the like, according to the material of the second adhesive layer 71. Furthermore, if residue of the second adhesive layer 71 remains on the bonding surface between the first wiring layer 21 and the second adhesive layer 71, plasma cleaning, ultrasonic cleaning, water washing, or solvent cleaning using alcohol may be performed.

### (Formation of Build-Up Layer)

Next, referring to FIG. 17, a step of forming a build-up layer, that is, a laminated layer including the first wiring layer 21 and the second wiring layer 22, will be described. FIG. 17 is a diagram illustrating the step of forming the build-up layer in the manufacturing method according to the first embodiment.

As shown in FIG. 17, the conductive electrodes 31 for electrically connecting the first wiring layer on the first surface side, and the conductive electrodes 32 for electrically connecting the second wiring layer on the second surface side, are formed on the first wiring layer 21 on the first surface 10a side of the glass substrate 60 and on the second wiring layer 22 on the second surface 10b side thereof. The conductive electrodes 31 and 32 can be formed by first forming vias in the insulating resin layer 25 using laser light, then forming a seed layer in the vias, and subsequently employing a semi-additive process, i.e., a series of processes including resist pattern formation, plating, resist stripping, seed layer removal, and insulating resin layer formation.

The first wiring layer 21 and the second wiring layer 22 each include one layer or a laminate of a plurality of layers, and the number of layers can be set depending on need. In FIG. 17, both the first wiring layer 21 and the second wiring layer 22 include two laminated layers.

The laser light used to form the conductive electrodes 31 and 32 may be different from that used to form the laser-modified portions 65. For example, it is preferable to use a pulsed laser such as a carbon dioxide laser or a UV-YAG laser, and a laser with a pulse width on the order of microseconds is suitable.

### (Formation of Connection Pads)

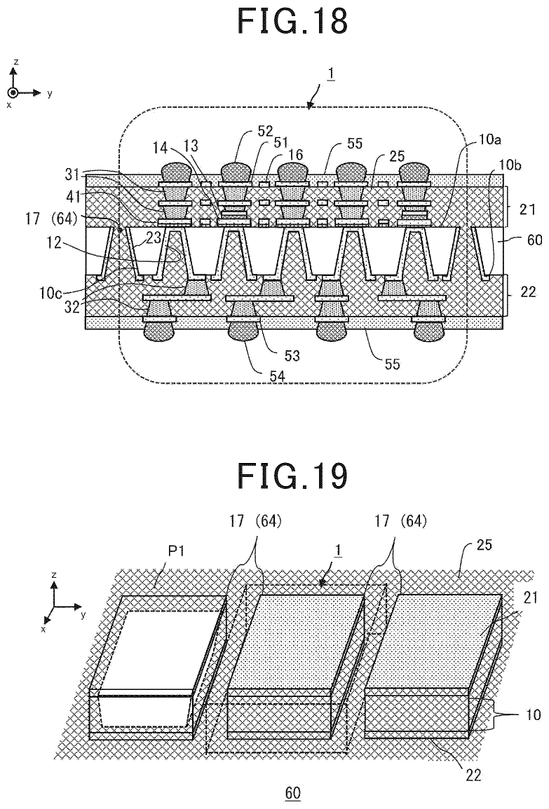

Next, the formation of connection pads will be described with reference to FIG. 18. FIG. 18 is a diagram illustrating the step of forming the connection pads in the manufacturing method according to the first embodiment. As shown here, after forming an outer protective film such as solder resist 55 on the first wiring layer 21 and the second wiring layer 22, semiconductor device bonding pads 51 are formed on the first wiring layer 21, and board bonding pads 53 are formed on the second wiring layer 22. A surface treatment such as Ni/Au, Ni/Pd/Au, IT, or OSP (water-soluble preflux) can be applied to the semiconductor device bonding pads 51 and the board bonding pads 53, and if necessary, the semiconductor device bonding solder 52 and board bonding solder 54 are formed to complete the multilayer wiring board. Note that Ni/Au refers to the use of both Ni and Au, and Ni/Pd/Au refers to the use of Ni, Pd, and Au together.

### (Multilayer Wiring Base Substrate)

Next, the multilayer wiring base substrate will be described with reference to FIG. 19. The glass substrate 60 shown in FIG. 18 is singulated into a plurality of multilayer wiring boards. However, the multilayer wiring boards 1 are connected by the insulating resin layer 25 and are in a state of being bonded together as a single unit, and can also be referred to as a multilayer wiring base substrate. That is, the multilayer wiring base substrate includes a plurality of multilayer wiring boards bonded together, each multilayer wiring board including a core substrate 10 having a first surface 10a, a second surface 10b opposing the first surface 10a, and a side surface portion 10c connecting a peripheral portion of the first surface 10a and a peripheral portion of the second surface 10b; a first wiring layer that is a wiring layer formed on the first surface; and a second wiring layer that is a wiring layer formed on the second surface. Each of the multilayer wiring boards has at least the side surface portion 10c of the core substrate 10 covered with a metal member and an insulating resin in this order from a center side of the core substrate, and is bonded to at least one other multilayer wiring board via the insulating resin. This will be specifically described below.

FIG. 19 is a perspective view illustrating an overview of the structure shown in FIG. 18. FIG. 19 omits components such as the connection pads for ease of understanding. The figure shows an arrangement of three portions each corresponding to the multilayer wiring board 1. The multilayer wiring board 1 corresponds to the portion enclosed by a broken line. It is defined as the portions of the first wiring layer 21, the second wiring layer 22, and the core substrate 10 enclosed by the separation grooves 17 formed in the xy plane and the yz plane. Although FIG. 19 shows three portions corresponding to multilayer wiring boards 1, a plurality of portions corresponding to multilayer wiring boards are included across the xy plane.

The structure shown in FIG. 18 can also be considered an intermediate product of the multilayer wiring board 1, namely a multilayer wiring base substrate. That is, the multilayer wiring base substrate includes a glass substrate 60 having a first surface 10a and a second surface 10b; a first wiring layer region that is a region including a wiring layer such as first wiring layer 21 formed on the first surface 10a; a second wiring layer region that is a region including a wiring layer such as second wiring layer 22 formed on the second surface 10b; a separation groove 17 penetrating from the first surface 10a to the second surface 10b and separating at least one multilayer wiring board 1 including the first and second wiring layer regions; a separation groove electrode 23 formed on the separation groove 17; and an insulating resin layer 25 formed on the separation groove electrode 23 and bonding adjacent multilayer wiring boards to each other.

### (Singulation)

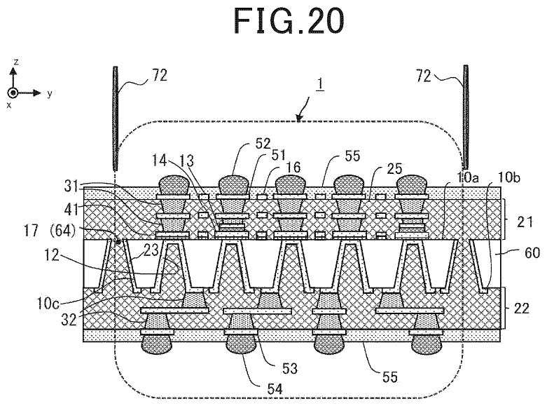

Next, the singulation of the multilayer wiring boards will be described with reference to FIG. 20. FIG. 20 is a cross-sectional view illustrating the singulation step in the manufacturing method according to the first embodiment. As shown in FIG. 20, the singulation of the multilayer wiring boards is performed along the singulation lines. FIG. 20 shows a case where blade dicing using a dicing blade 72 is assumed, but methods other than blade dicing, such as laser and scribing, may also be used. Singulation may also be performed by combining blade dicing, laser, and scribing.

Since the side surface portion 10c of the glass substrate 60 is covered with metal, it is possible to suppress dragging of the resin by the dicing blade during singulation.

### (Flowchart of the Manufacturing Method According to First Embodiment)

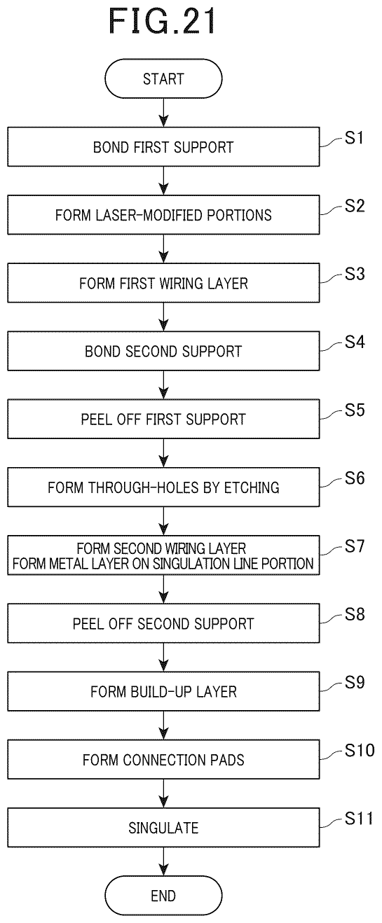

The steps described above are summarized in a flowchart. FIG. 21 illustrates a flowchart of the manufacturing method according to the first embodiment.

Step S1 is the step of bonding the first support. The first support 61 is bonded to the base substrate such as glass substrate 60. The first embodiment showed an exemplary case where an adhesive layer containing hydroxyl groups is used.

Step S2 is the step of forming the laser-modified layer. Laser-modified portions are formed in the base substrate (glass substrate 60). The laser irradiation can be performed from the surface, e.g., the second surface 60b, opposite to the surface to which the first support 61 is bonded, e.g., the first surface 60a. The laser-modified portions serve as the starting point for the through-holes 11 and separation grooves 17.

Step S3 is the step of forming the first wiring layer 21. Electrodes, wiring, capacitors, inductors, or the like can be formed in the first wiring layer 21.

Step S4 is the step of bonding the second support 70. The second support 70 is bonded onto the first wiring layer 21.

Step S5 is the step of peeling the first support 61. The base substrate (glass substrate 60) and the first support can be separated at the adhesive layer portion.

Step S6 is the step of forming the through-holes 11 by etching. Etching is performed from the second surface 60b side of the base substrate (glass substrate 60) to remove the laser-modified portions. The through-holes 11 or separation grooves 17 (singulation lines 64) are formed in the portions where the laser-modified portions have been removed.

Step S7 is the step of forming the second wiring layer. A metal layer is formed in the through-holes 11 and the separation grooves 17. An insulating resin is deposited on the second surface 60b side to form the insulating resin layer 25, thereby forming the second wiring layer. Specifically, a seed layer is formed and plating is performed to form through-electrodes in the through-holes of the base substrate, and electrodes and wiring that are electrically connected to the through-electrodes are formed. Simultaneously, a metal layer such as separation groove electrode 23 is also formed on the side surface portion 10c of the singulation lines 64. An insulating resin deposition step is performed after that.

Step S8 is the step of peeling the second support 70. The second support 70 is separated from the base substrate 60.

Step S9 is the step of forming the build-up layer. Electrodes and wiring are formed on the first and second wiring layers 21 and 22.

Step S10 is the step of forming the connection pads. Protective films are formed on the first wiring layer 21 and the second wiring layer 22, and then connection pads are formed.

Step S11 is the singulation step. Dicing or the like is performed on the base substrate (glass substrate 60) to separate the multilayer wiring boards 1.

### First Modification

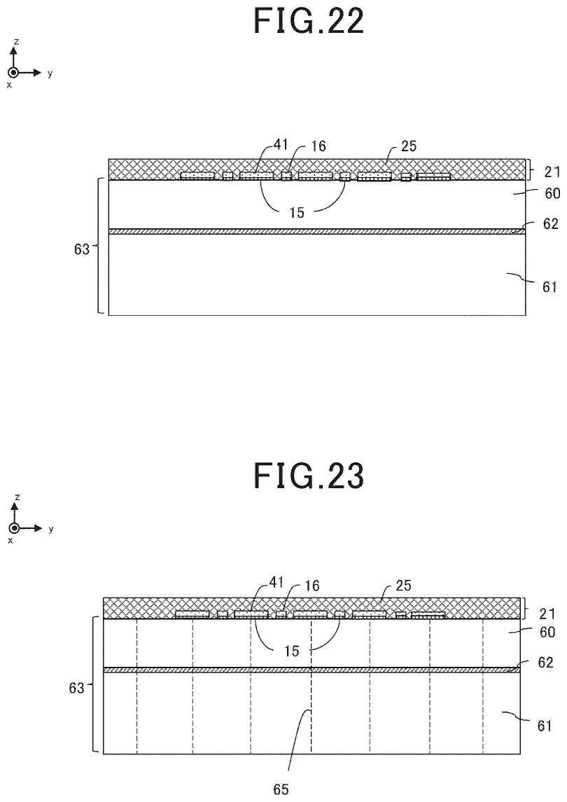

Next, a manufacturing method as a first modification will be described with reference to FIGS. 22 to 24.

The first modification differs from the first embodiment in that the step of forming the laser-modified portions is performed after the step of forming the first wiring layer.

In the following description, components that are the same as or similar to those of the first embodiment are given the same reference signs, and will not be described in detail or at all.

FIG. 22 is a cross-sectional view illustrating the step of forming the first wiring layer in the manufacturing method according to the first modification. In the first modification, following the step of bonding the first support, the first wiring layer 21 is formed on the glass substrate 60 of the laminated structure 63. At this time, after forming a seed layer including the hydrofluoric acid-resistant metal layer 15 on the glass substrate 60, the through-electrode connection portions 41 and wiring 16 are formed using a semi-additive process (SAP). After removing the seed layer which is no longer needed, the insulating resin layer 25 is formed.

The materials and deposition methods for the hydrofluoric acid-resistant metal layer, through-electrode connection portions, and the like are the same as those in the first embodiment.

### (Formation of Laser-Modified Portions)

Next, referring to FIG. 23, the laser-modified portion formation step in the first modification will be described. FIG. 23 is a cross-sectional view illustrating the step of forming laser-modified portions in the manufacturing method according to the first modification. As illustrated here, the laminated structure 63 is irradiated with laser light from the surface of the first support 61 to form the laser-modified portions 65.

Since laser-modified portions are also formed along the singulation lines of the multilayer wiring board 1 in this step, it is possible to obtain the same side surface shape as that of the multilayer wiring board 1 described in the first embodiment.

### (Steps After Bonding of Second Support)

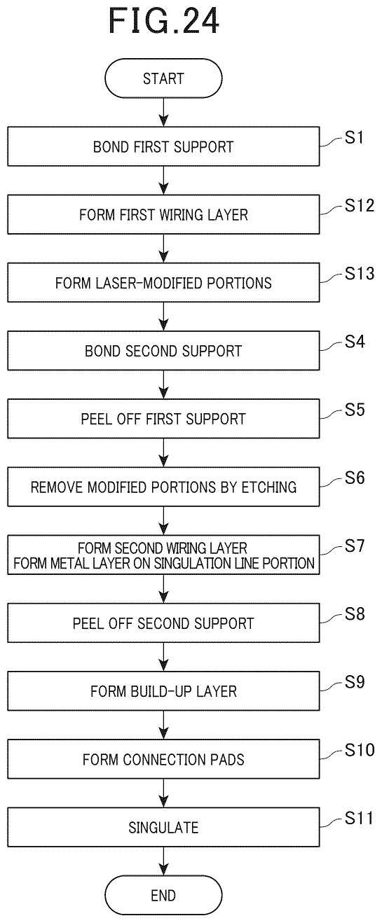

FIG. 24 illustrates a flowchart of a manufacturing method according to the first modification. In the first modification, except for the first wiring layer formation step (step S12) and the laser-modified portion formation step (step S13), the manufacturing method is the same as that of the first embodiment.

### Second Modification

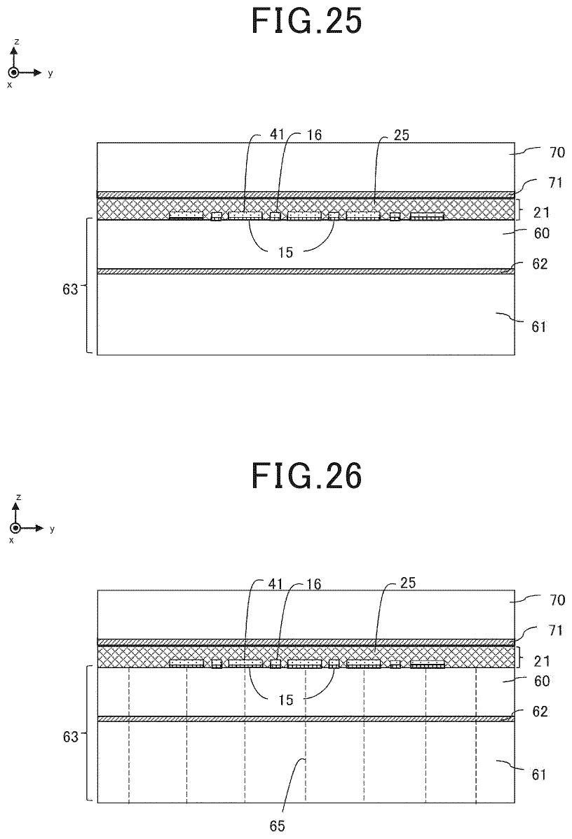

Next, a manufacturing method as a second modification will be described with reference to FIGS. 25 to 27.

The second modification differs from the first embodiment in that the laser modification step is performed after the step of bonding the second support.

In the following description, components that are the same as or similar to those of the first embodiment or the first modification are given the same reference signs, and will not be described in detail or at all.

### (Bonding of First Support and Formation of First Wiring Layer)

In the manufacturing method according to the second modification, the initial steps, that is, the step of bonding the first support and the step of forming the first wiring layer, are identical to those in the first embodiment, and therefore their descriptions are omitted.

### (Bonding of Second Support)

Next, referring to FIG. 25, the step of bonding the second support in the second modification will be described. FIG. 25 is a cross-sectional view illustrating the step of bonding the second support in the manufacturing method according to the second modification. In the second modification, the second adhesive layer 71 and the second support 70 are formed on the first wiring layer 21 of the laminated structure 63.

### (Formation of Laser-Modified Portions)

FIG. 26 is a cross-sectional view illustrating the step of forming laser-modified portions in the manufacturing method according to the second modification. In the laser-modified portion formation step of the second modification, the laminated structure 63 is irradiated with laser light from the first support 61 side to form the laser-modified portions 65.

Since laser-modified portions are also formed along the singulation lines of the multilayer wiring board 1 in this step, it is possible to obtain the same side surface shape as that of the multilayer wiring board 1 described in the first embodiment.

### (Steps After Peeling First Support)

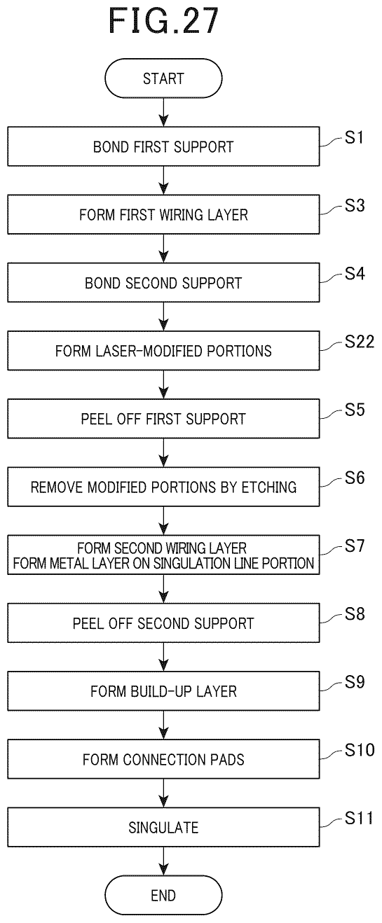

FIG. 27 illustrates a flowchart of a manufacturing method according to the second modification. In the second modification, the manufacturing method is the same as that of the first embodiment, except that the laser-modified portion formation step (step S22) is performed at a different stage.

### Advantageous Effects

According to the first embodiment, and the first and second modifications of the present disclosure, by protecting the side surfaces of the core substrate of the multilayer wiring board with resin and a metal member, the μ-cracks occurring on the glass side surfaces are filled. This allows sufficient adhesion to be maintained between the resin and the core substrate, thereby suppressing delamination of the resin and avoiding damage to the core substrate. Details will be described below with reference to Examples and Comparative Examples. Each of the Examples described below is merely an example for implementing the present disclosure, and the present disclosure should not be construed as being limited to these embodiments.

### Description of Examples

Samples at various levels were prepared with the opening width W1 of the separation groove 17 (singulation line 64) shown in FIG. 9 of the first embodiment set to 300 μm.

The dicing along the singulation line 64, the temperature cycling test conditions, and the evaluation method are as follows.

### Dicing

Blade used: R07-SD600-BB200-75 54×0.15A2×40
Equipment used: DAD322

### Temperature Cycling Test

Test conditions: One cycle consists of temperature changes through −55 °C, room temperature (RT), and 125 °C, with each temperature held for 30 minutes, and the test is performed for up to 1000 cycles.
Observation method: The side surface of the substrate is observed with a metallurgical microscope at 100× and 500× magnification to evaluate whether the glass substrate is damaged.

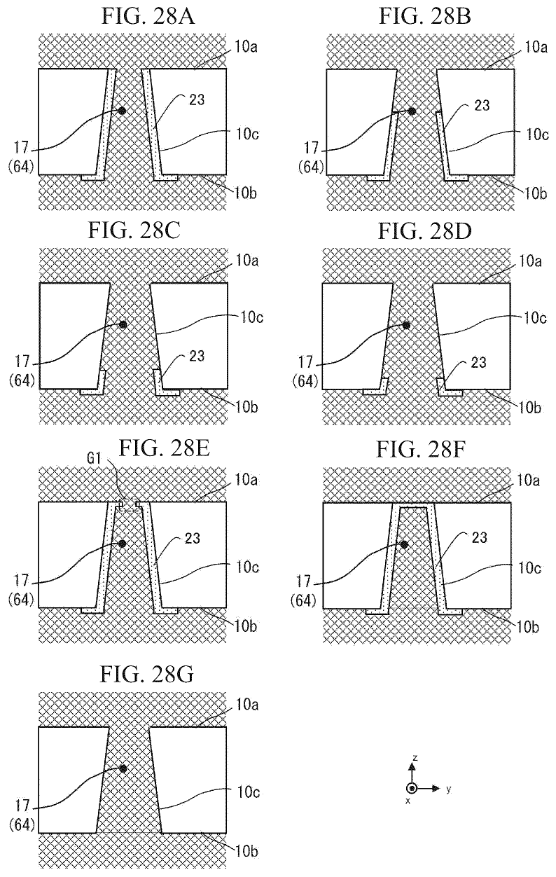

Next, each sample will be described with reference to FIGS. 28A, 28B, 28C, 28D, 28E, 28F and 28G. FIGS. 28A, 28B, 28C, 28D, 28E, 28F and 28G are enlarged views showing a boundary portion between the singulation line 64 portion and the glass substrate 60 for each of the prepared samples (Examples 1 to 5) and Comparative Examples 1 and 2.

### Example 1

Example 1 was formed using the method of the first embodiment, and as shown in FIG. 28A, the coverage of the metal layer (separation groove electrode 23) on the side surface portion 10c was set to 100%. The coverage represents the proportion of the side surface portion 10c that is covered in the separation groove 17. A coverage of 100% indicates a state in which the side surface portion 10c is entirely covered by the metal layer, or in other words, a state in which no portion of the glass member of the side surface portion 10c is exposed in the separation groove 17.

### Example 2

Example 2 was formed using the method of the first embodiment, and as shown in FIG. 28B, the coverage of the metal layer on the side surface portion was set to 50%.

### Example 3

Example 3 was formed using the method of the first embodiment, and as shown in FIG. 28C, the coverage of the metal layer on the side surface portion was set to 20%.

### Example 4

Example 4 was formed using the method of the first embodiment, and as shown in FIG. 28D, the coverage of the metal layer on the side surface portion was set to 10%.

### Example 5

Example 5 was formed using the method of the first embodiment, and as shown in FIG. 28E, in addition to setting the coverage of the metal layer on the side surface portion 10c to 100%, a metal layer was also formed at the bottom of the separation groove 17, i.e., the opening on the first surface 10a side of the separation groove 17, with a gap G1 provided. The gap G1 is a space for the dicing blade to pass through. If a dicing blade is to be passed through the separation groove 17 (singulation line 64), it is preferable that the width of the gap G1 be larger than the width of the dicing blade (150 μm). In other words, it is preferable to form the metal layer such that the edge portions of the metal layer are located outside the path of the dicing blade.

### Comparative Example 1

Comparative Example 1 was formed using the method of the first embodiment, and as shown in FIG. 28F, in addition to setting the coverage of the metal layer on the side surface portion 10c to 100%, a metal layer was also formed over the entire bottom surface of the separation groove.

### Comparative Example 2

Comparative Example 2 has a structure formed by the method of the first embodiment in which the side surface portion 10c is exposed as shown in FIG. 28G, and no metal layer is formed.

Table 1 shows the evaluation results of the Examples and Comparative Examples. Regarding the overall evaluation, samples were considered acceptable, denoted as “pass” in the “overall evaluation” column, when they exhibited no issues in the core substrate cracking evaluation beyond 1,000 temperature cycles, denoted as “pass” in the “evaluation” column, and caused no damage to the dicing blade device during cutting.

TABLE 1

| | | | | Core substrate | | | |
|---|---|---|---|---|---|---|---|
| | Side surface | Side surface | Bottom | cracking evaluation | | Blade | Overall |
| Item | configuration | metal coverage | metal | Result | Evaluation | damage | evaluation |
| Ex. 1 | Resin/Metal/Glass | 100% | None | 2000 cycles | Pass | No | Pass |
| | | | | OK | | | |
| Ex. 2 | Resin/Metal/Glass | 50% | None | 1800 cycles | Pass | No | Pass |
| | | | | OK | | | |
| Ex. 3 | Resin/Metal/Glass | 20% | None | 1600 cycles | Pass | No | Pass |
| | | | | OK | | | |
| Ex. 4 | Resin/Metal/Glass | 10% | None | 1400 cycles | Pass | No | Pass |
| | | | | OK | | | |
| Ex. 5 | Resin/Metal/Glass | 100% | 50 μm | 2000 cycles | Pass | No | Pass |
| | | | | OK | | | |
| Comp. | Resin/Metal/Glass | 100% | 300 μm | 400 cycles | Pass | Yes | Fail |
| Ex. 1 | | | (entire bottom) | OK | | | |
| Comp. | Resin/Glass | None | — | 1000 cycles | Fail | No | Fail |
| Ex. 2 | | | | OK | | | |

First, the results of confirming whether the dicing blade was damaged during dicing will be described. As shown in Table 1, no blade damage was confirmed in Examples 1, 2, 3, 4, and 5 and Comparative Example 2. On the other hand, blade damage was confirmed in Comparative Example 1. It was confirmed that the presence of metal on the separation groove (singulation line) caused wear of the metal and the metal dicing blade.

Next, the results of the temperature cycling test will be described. As shown in Table 1, Examples 1, 2, 3, 4, and 5 exhibited no failures even at 1,000 cycles. On the other hand, Comparative Example 1 failed at 400 cycles. Analysis of the failed sample confirmed defects such as the occurrence of microcracks in the core material. It is considered that during dicing with the blade, stress due to chipping between the blade and the metal caused the generation of microcracks. In Comparative Example 2, failure occurred at 1,000 cycles.

In the samples that passed, separation grooves were formed in advance along the singulation lines, and the edge portions of the separation grooves were protected with resin or the like, thereby suppressing crack generation in the core material.

### Advantageous Effects

By protecting the side surface portion 10c of the core substrate 10 with insulating resin, delamination between the resin and the core substrate is avoided. As a result, damage to the core substrate is avoided, and high reliability of the multilayer wiring board can be achieved.

The scope of the present disclosure is not limited to the exemplary embodiments illustrated and described herein, but includes various modifications. For example, the above embodiments have been described in detail to clearly explain the present disclosure, but the present disclosure need not include all the components described.

Furthermore, it is possible to replace part of the components of one embodiment with components of another embodiment, and it is also possible to add components of one embodiment to another embodiment. It is also possible to add other components to, remove components from, or replace components of each embodiment.

The present disclosure encompasses all embodiments that achieve effects equivalent to those intended by the present disclosure.

For example, the present disclosure describes forming laser-modified portions after bonding the first support to the glass substrate and subsequently peeling off the first support, but is not limited thereto. For example, the laser-modified portions may be formed without using a first support, and the laser-modified portions may be etched to the desired thickness in the through-hole formation step.

Aspects that may constitute the content of the present disclosure are described below, but the disclosure is not limited thereto.

### (Aspect 1)

A multilayer wiring base substrate includes a plurality of multilayer wiring boards bonded together, each multilayer wiring board including a core substrate having a first surface, a second surface opposing the first surface, and a side surface portion connecting a peripheral portion of the first surface and a peripheral portion of the second surface; a first wiring layer that is a wiring layer formed on the first surface; and a second wiring layer that is a wiring layer formed on the second surface. Each of the multilayer wiring boards has at least the side surface portion of the core substrate covered with a metal member and an insulating resin in this order from a center side of the core substrate, and is bonded to at least one other multilayer wiring board via the insulating resin.

### (Aspect 2)

A multilayer wiring board includes a core substrate having a first surface, a second surface opposing the first surface, and a side surface portion connecting peripheral portions of the first surface and the second surface; a first wiring layer that is a wiring layer formed on the first surface; and a second wiring layer that is a wiring layer formed on the second surface. At least the side surface portion of the core substrate is covered with a metal member and an insulating resin in this order.

### (Aspect 3)

In the multilayer wiring board according to aspect 2, 10% or more of the side surface portion of the core substrate is covered with the metal member.

### (Aspect 4)

In the multilayer wiring board according to aspect 2 or 3, the metal member on the side surface portion of the core substrate includes a film member deposited by sputtering as a seed layer.

### (Aspect 5)

In the multilayer wiring board according to any one of aspects 2 to 4, the metal member on the side surface portion of the core substrate includes a metal layer formed by plating.

### (Aspect 6)

A method for manufacturing a multilayer wiring board includes forming a laser-modified portion in a base substrate having a first surface and a second surface opposing the first surface; forming a first wiring layer on the first surface; performing etching from the second surface side to form a through-hole and a separation groove; forming a metal layer in the through-hole and the separation groove; and depositing an insulating resin on the second surface side to form an insulating resin layer, and forming a second wiring layer.

### (Aspect 7)

In the method for manufacturing a multilayer wiring board according to aspect 6, in the forming the metal layer, a gap through which a dicing blade passes is formed in the metal layer.

### (Aspect 8)

An intermediate product of a multilayer wiring board includes a base substrate having a first surface and a second surface; at least one first wiring layer region that is a region including a wiring layer formed on the first surface; at least one second wiring layer region that is a region including a wiring layer formed on the second surface; a separation groove that extends from the first surface to the second surface to singulate at least one multilayer wiring board including the first and second wiring layer regions; a separation groove electrode formed on the separation groove; and an insulating resin layer formed on the separation groove electrode and bonding adjacent multilayer wiring boards to each other.

What is claimed is:

1. A multilayer wiring base substrate, comprising:
a plurality of multilayer wiring boards bonded together,
each multilayer wiring board including:
a core substrate having a first surface, a second surface opposing the first surface, and a side surface portion connecting a peripheral portion of the first surface and a peripheral portion of the second surface;
a first wiring layer that is a wiring layer formed on the first surface; and
a second wiring layer that is a wiring layer formed on the second surface, wherein each of the multilayer wiring boards:
has at least the side surface portion of the core substrate covered with a metal member and an insulating resin in this order from a center side of the core substrate, and
is bonded to at least one other multilayer wiring board via the insulating resin.

2. A multilayer wiring board comprising:
a core substrate having a first surface, a second surface opposing the first surface, and a side surface portion connecting a peripheral portion of the first surface and a peripheral portion of the second surface;
a first wiring layer that is a wiring layer formed on the first surface; and
a second wiring layer that is a wiring layer formed on the second surface, wherein
at least the side surface portion of the core substrate is covered with a metal member and an insulating resin in this order.

3. The multilayer wiring board according to claim 2, wherein
10% or more of the side surface portion of the core substrate is covered with the metal member.

4. The multilayer wiring board according to claim 2, wherein
the metal member on the side surface portion of the core substrate includes a film member deposited by sputtering as a seed layer.

5. The multilayer wiring board according to claim 2, wherein
the metal member on the side surface portion of the core substrate includes a metal layer formed by plating.

6. The multilayer wiring board according to claim 2, wherein
the core substrate has one or more through-electrodes penetrating from an opening formed on the first surface of the core substrate to an opening formed on the second surface,
the first and second wiring layers are electrically connected via the through-electrodes, and
the multilayer wiring board has one or more capacitors each consisting of a lower electrode disposed on the first wiring layer, and a dielectric layer and an upper electrode sequentially laminated on the lower electrode.

7. The multilayer wiring board according to claim 6, wherein
the through-electrode closes the opening on the first surface side in the first wiring layer, and
the lower electrode of at least one of the capacitors closes the through-electrode in the first wiring layer.

8. The multilayer wiring board according to claim 6, wherein
the dielectric layer has a thickness in the range of 10 nm or more and 5 μm or less.

9. The multilayer wiring board according to claim 6, wherein
the multilayer wiring board has an inductor formed in the first wiring layer.

10. The multilayer wiring board according to claim 2, wherein
the first and second wiring layers include an insulating resin layer, and
the insulating resin layer is formed of a resin of the same type as the insulating resin covering a side surface of the core substrate.

11. The multilayer wiring board according to claim 10, wherein
the insulating resin layer has a relative permittivity in the range of 3.1 or more and 3.5 or less, and a dielectric loss tangent in the range of 0.002 or more and 0.012 or less.

12. A method for manufacturing a multilayer wiring board, the method comprising:
forming a laser-modified portion in a base substrate having a first surface and a second surface opposing the first surface;
forming a first wiring layer on the first surface;
performing etching from the second surface side to form a through-hole and a separation groove;
forming a metal layer in the through-hole and the separation groove; and
depositing an insulating resin on the second surface side to form an insulating resin layer, and forming a second wiring layer.

13. The method for manufacturing a multilayer wiring board according to claim 12, wherein
in the step of forming the metal layer, a gap through which a dicing blade passes is formed in the metal layer.

14. A multilayer wiring base substrate comprising:
a base substrate having a first surface and a second surface;
a first wiring layer region that is a region including a wiring layer formed on the first surface;
a second wiring layer region that is a region including a wiring layer formed on the second surface;
a separation groove that extends from the first surface to the second surface to separate at least one multilayer wiring board including the first and second wiring layer regions;
a separation groove electrode formed on the separation groove; and
an insulating resin layer formed on the separation groove electrode and bonding adjacent multilayer wiring boards to each other.
